(19) United States
(12) Patent Application Publication
(10) Pub. No.: US 2020/0084915 A1
(43) Pub. Date: Mar. 12, 2020

(54) Mainframe box

(71) Applicant: Xiaoxiao Wu, Tianjin City (CN)

(72) Inventor: Xiaoxiao Wu, Tianjin City (CN)

(21) Appl. No.: 16/681,834

(22) Filed: Nov. 13, 2019

(30) Foreign Application Priority Data
Apr. 26, 2019 (CN) 2019103438400

(51) Int. Cl. H05K 7/20; G06F 1/20

(52) U.S. Cl. CPC H05K 7/20263; H05K 7/20272; H05K 7/20181; G06F 1/20

(57) ABSTRACT

The invention discloses a mainframe box, which comprises a box body, and the starting driving wheel starts to drive the driven wheel to engage, and the water in the water storage block is transported into the pipeline network through the water outlet pipe, and the temperature of the air in the bottom outlet is lowered, and the motor is started. The main shaft and the second bevel gear rotate, and the cooling component in the main box can reduce the temperature of the water in the water storage block by using the temperature of the ice crystal block, and can lower the temperature of the air in the bottom outlet through the pipe network in the bottom outlet, under the host The blowing member provided in the bottom outlet can blow the low-temperature air in the bottom outlet into the inner cavity, and the main body sucks the low-temperature air in the inner cavity while dissipating heat.

### CROSS-REFERENCES TO RELATED APPLICATIONS

The present application claims priority from Chinese application No. 2019103438400 filed on Apr. 26, 2019 which is hereby incorporated by reference in its entirety.

### TECHNICAL FIELD

The invention relates to the field of computer accessories, in particular to a mainframe box.

### BACKGROUND OF THE INVENTION

The computer host generates a lot of heat when it is used. The temperature is high in summer, the heating speed of the host is fast, the heat dissipation capacity is low, and the high-performance game consoles are more and more. The demand for heat dissipation is continuously improved, and the existing water-cooled host is The heat dissipation capability is strong, but the heat dissipation capability will be saturated for a long time, and the dust is easily accumulated in the main box, which is inconvenient to clean.

### CONTENT OF THE INVENTION

It is an object of the present invention to provide a main chassis for overcoming the above-discussed deficiencies in the prior art.

A main body box according to an embodiment of the present invention includes a box body having an inner cavity opening to the front, a main body is disposed in the inner cavity, and the rear side wall of the inner cavity is provided with an opening backward a rear outlet end of the casing, wherein a first screen passing through the rear outlet is inserted and installed, and a bottom outlet of the inner cavity is provided with a bottom outlet opening downward, and the right end surface of the casing is inserted and installed a second filter screen penetrating the bottom outlet, wherein the bottom outlet is provided with a blowing member for blowing upward, and a cooling member for lowering the temperature of the wind blown by the blowing member is disposed between the bottom outlet and the casing. The right side wall of the inner cavity is provided with a connection hole opening to the right, the connection hole can be placed with a data line connected to the main body, and the right end surface of the box body is provided with a fixing component for fixing the data line, the box The front end of the body is provided with a switch door component that closes the inner cavity and facilitates opening the main body.

In a further technical solution, the blowing component comprises a connecting rod symmetrical between the left and right walls of the bottom outlet, and a rotating seat is arranged between the connecting rods on the left and right sides, and the rotating seat is mounted between the upper and lower rotating seats. a fan shaft, the fan shaft is provided with a sprocket, and the chain is driven between the sprocket wheels on the front and rear sides, the fan shaft is provided with a blade, and the fan shaft on the front side is provided with a first bevel gear a motor is disposed on a left side wall of the bottom outlet, a right side of the motor is coupled to the main shaft, and two shaft stabilizing blocks are disposed between the upper and lower connecting rods, and the shaft stabilizing block is rotatably engaged with the main shaft. A second bevel gear is disposed at a right end of the main shaft, the second bevel gear meshes with the first bevel gear, and a third filter mesh is disposed between the inner wall of the bottom outlet.

In a further technical solution, the cooling component comprises a foam block located in the inner wall of the bottom outlet and the casing, and a water storage block is arranged in the foam block of the vertical portion, and ice crystals can be placed in the left end of the water storage block. Block, the left end of the foam block is covered by a screw cover, and the bottom end of the water storage block is connected to the water outlet pipe, and the water outlet pipe extends right into the bottom outlet and connects the pipe network, and the right end of the pipe network is connected a return pipe, which is connected to the water storage block after bypassing the bottom outlet, wherein the water outlet pipe is provided with a pump chamber, and a driving wheel is dynamically mounted between the left and right walls of the pump chamber, the pump chamber A driven wheel is rotatably mounted between the left and right walls, and the driven wheel is engaged with the driving wheel.

In a further technical solution, the fixing component includes a rotating pin rotatably mounted on the right end surface of the casing, the right end surface of the rotating pin is provided with a buckle, and the right end surface of the casing is hingedly mounted with a buckle. The buckle block is provided with a buckle groove, and the buckle groove can be mated with the rotation pin and the buckle.

In a further technical solution, the switch door component includes a door slot that communicates with the inner cavity at a front end surface of the box body, and the bottom wall of the door groove is rotated to install a door, and the top end surface of the door is set There is a sliding groove, an upper sliding groove is arranged in the top wall of the door groove, and the sliding door is slidably mounted between the blocking door and the top wall of the door groove, and the upper and lower end faces of the sliding door are symmetrically slipped. And the slider is slidably engaged with the upper sliding groove and the sliding groove.

The invention has the advantages that the structure of the invention is simple and convenient to operate, and the cooling component in the main box can reduce the temperature of the water in the water storage block by using the temperature of the ice crystal block, and can be used in the bottom outlet through the pipeline network in the bottom outlet. The air temperature is lowered, and the blowing member provided in the bottom outlet below the main unit can blow the low-temperature air in the bottom outlet into the inner cavity, and the host can inhale the low-temperature air in the inner cavity during heat dissipation, which can better cool down, and is worth promoting.

### BRIEF DESCRIPTION OF THE DRAWINGS

FIG. 1 is a schematic view of the overall structure of the present invention;

FIG. 2 is a schematic view of the front side structure of the present invention;

FIG. 3 is a cross-sectional structural view of the A-A direction of FIG. 1;

FIG. 4 is an enlarged schematic view of a portion B in FIG. 1;

FIG. 5 is a cross-sectional structural view taken along line C-C of FIG. 1;

FIG. 6 is a cross-sectional structural view of the D-D direction of FIG. 1;

FIG. 7 is a cross-sectional structural view of the E-E direction of FIG. 2;

FIG. 8 is a cross-sectional structural view of the F-F direction of FIG. 4;

FIG. 9 is a schematic view showing the structure of the buckle.

### DETAILED DESCRIPTION OF THE INVENTION

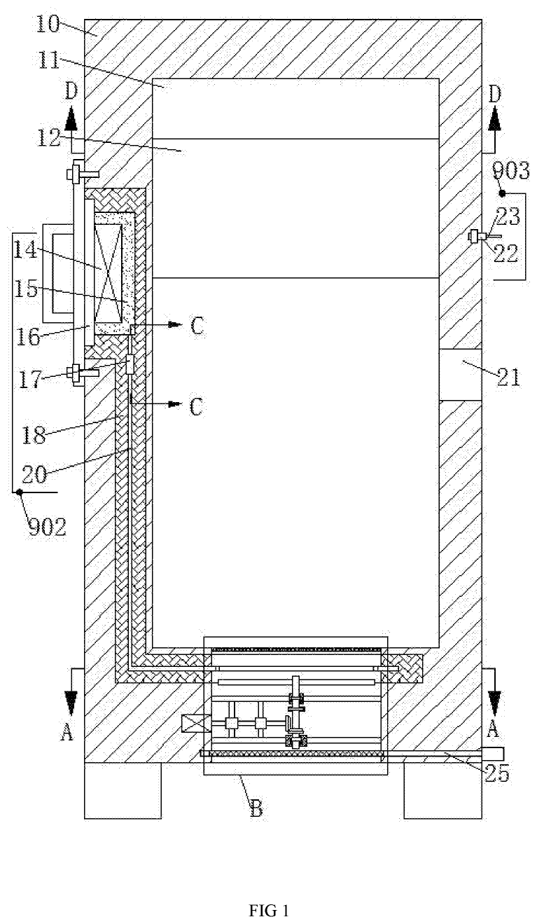

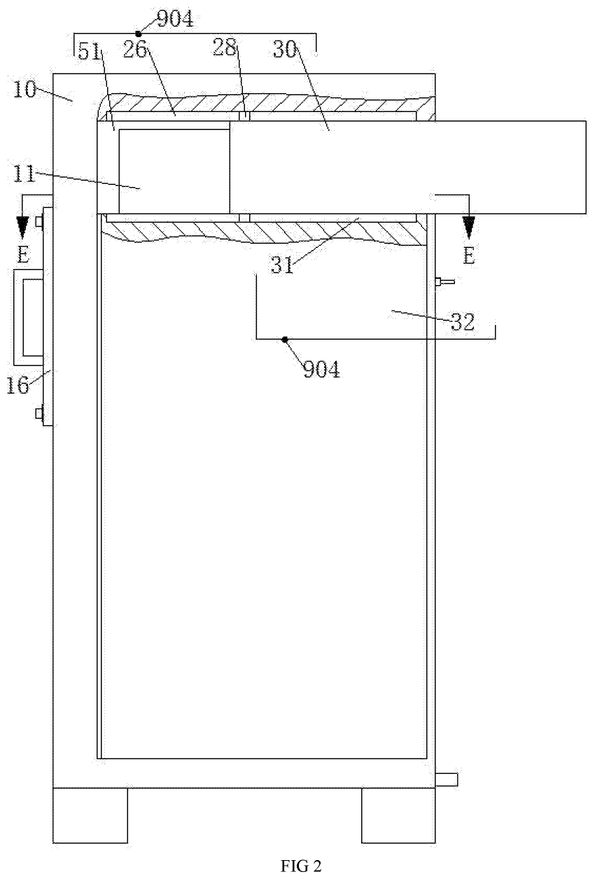

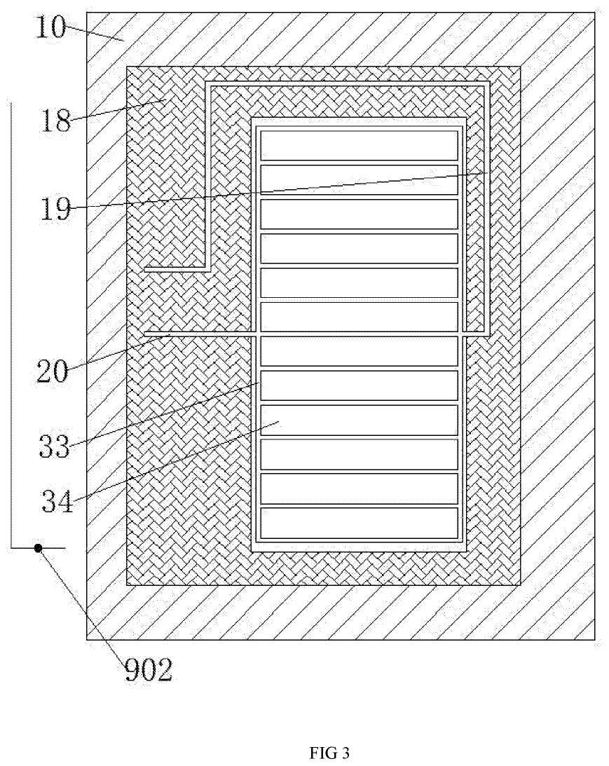

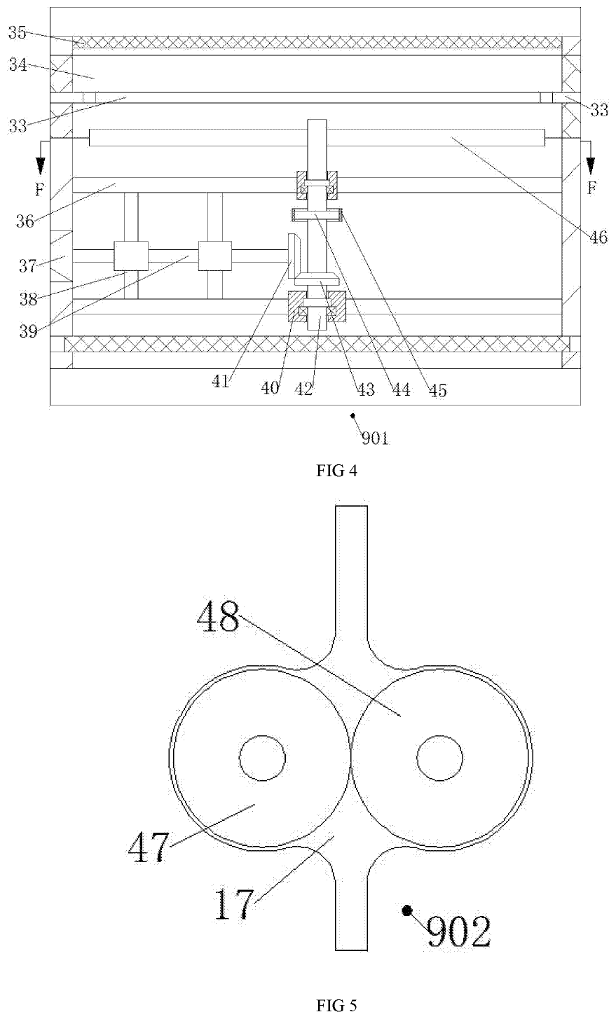

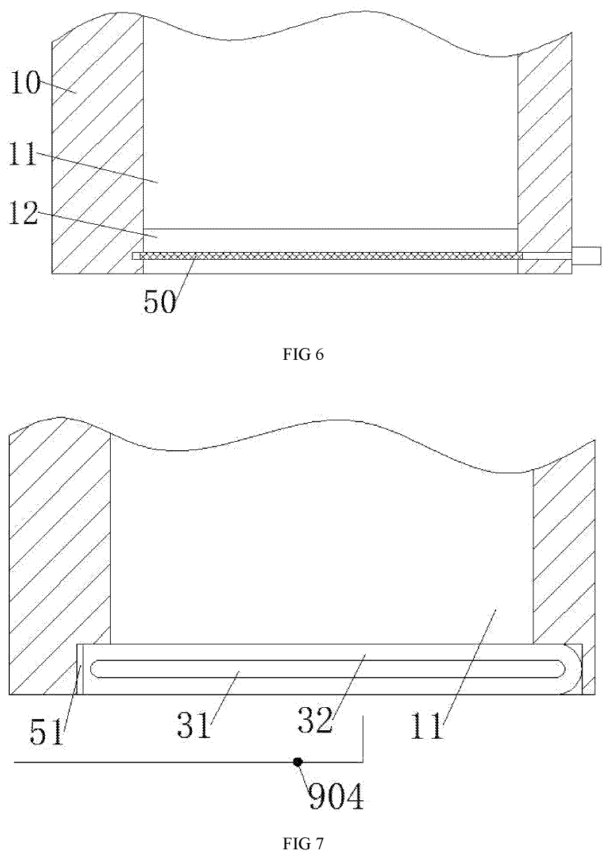

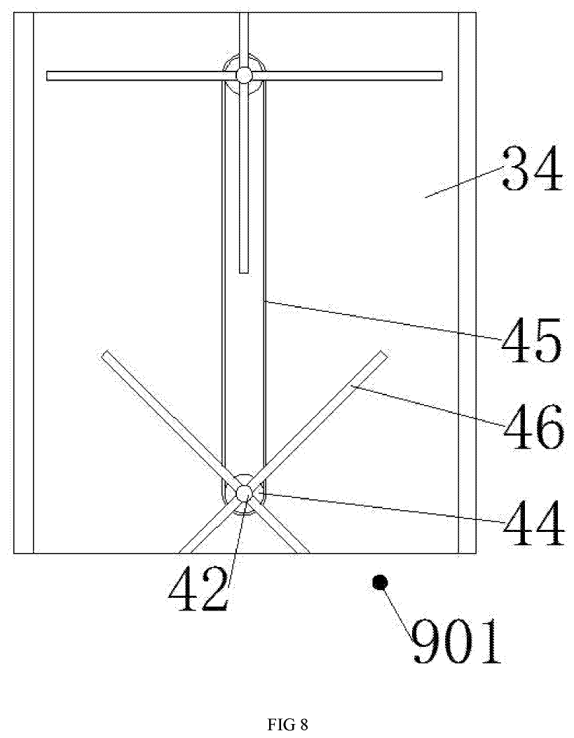

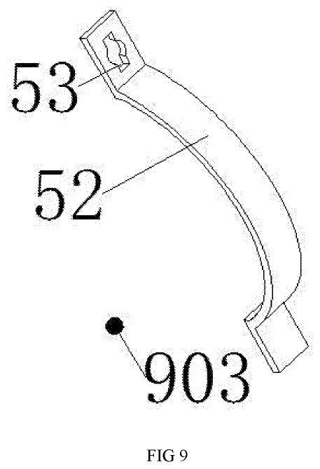

The present invention will now be described in detail with reference to FIGS. 1-9. For convenience of description, the orientations described below are now defined as follows: the up, down, left, and right front and rear directions described below are consistent with the up, down, left, and right front and rear directions of the projection relationship of FIG. 1 itself. Referring to FIGS. 1-9, a main chassis according to an embodiment of the present invention includes a case 10 in which a cavity 11 having an opening forward is disposed, and a host is placed in the cavity 11, The rear side wall of the inner chamber 11 is provided with an opening rearward opening 12, and the right side end surface of the box body 10 is inserted and inserted through the first screen 50 passing through the rear outlet 12, and the bottom wall of the inner chamber 11 is provided with an opening. a bottom bottom outlet 34, the right end surface of the casing 10 is inserted and inserted through the second screen 25 passing through the bottom outlet 34, and the bottom outlet 34 is provided with a blowing member 901 for blowing upward, the bottom outlet A cooling member 902 is provided between the 34 and the casing 10 for reducing the temperature of the wind blown by the blowing member 901. The right side wall of the inner chamber 11 is provided with a wiring hole 21 opening to the right, and the wiring hole 21 is The data line connected to the host is placed, and the right end surface of the box 10 is provided with a fixing member 903 for fixing the data line, and the front end of the box 10 is provided with a switch door for closing the inner cavity 11 and conveniently opening the host, component 904.

The blowing member 901 includes a connecting rod 36 which is vertically symmetrically disposed between the left and right walls of the bottom outlet 34. The rotating bracket 40 is disposed between the connecting rods 36 on the left and right sides, and the rotating seat 40 is rotated between the upper and lower sides. A fan shaft 42 is mounted. The fan shaft 42 is provided with a sprocket 44. The chain 45 is driven between the front and rear sprocket wheels 44. The fan shaft 42 is provided with blades 46, and the fan on the front side. The shaft 42 is provided with a first bevel gear 43. The left side wall of the bottom outlet 34 is provided with a motor 37. The right side of the motor 37 is connected to the main shaft 39, and two shaft stabilizing blocks are arranged between the upper and lower connecting rods 36. 38. The shaft stabilizing block 38 is rotatably engaged with the main shaft 39. The right end of the main shaft 39 is provided with a second bevel gear 41. The second bevel gear 41 meshes with the first bevel gear 43. The bottom outlet A third filter 35 is disposed between the inner walls of the 34. The starter motor 37 drives the fan shaft 42 and the sprocket 44 to rotate.

The sprocket 44 drives the chain 45 and the fan shaft 42 on the rear side to rotate. The fan shaft 42 drives the blade 46 to rotate and starts to blow.

The cooling member 902 includes a foam block 18 located in the inner wall of the bottom outlet 34 and the casing 10, and a water storage block 15 is disposed in the foam block 18 of the vertical portion, and the left end of the water storage block 15 is An ice crystal block 14 may be placed, and the left end of the foam block 18 is covered by a screw to cover the mounting cover 16, and the bottom end of the water storage block 15 is connected to the water outlet pipe 20, and the water outlet pipe 20 extends right into the bottom outlet 34 and The pipe network 33 is connected, and the right end of the pipe network 33 is connected to a return pipe 19, and the return pipe 19 is connected to the water storage block 15 after being bypassed by the bottom outlet 34. The water outlet pipe 20 is provided with a pump chamber 17 The driving wheel 47 is dynamically mounted between the left and right walls of the pump chamber 17. The driven wheel 48 is rotatably mounted between the left and right walls of the pump chamber 17. The driven wheel 48 meshes with the driving wheel 47 to freeze the ice crystal block 14 It is placed at the left end of the water storage block 15, and the water in the water storage block 15 absorbs the temperature of the ice crystal block 14 and then starts to cool down, closes the cover plate 16, and activates the driving wheel 47 to start the driving of the driven wheel 48 to bring the water in the water storage block 15. It is transported into the pipe network 33 through the water outlet pipe 20, and the temperature of the air in the bottom outlet 34 is lowered, and the temperature is low. The air is blown upward into the inner chamber 11 by the blowing member 901, and the water flows upward through the return pipe 19 back into the water storage block 15.

The fixing member 903 includes a rotating pin 22 rotatably mounted on the right end surface of the casing 10. The right end surface of the rotating pin 22 is provided with a buckle 23, and the right end surface of the casing 10 is hingedly mounted with the buckle 52. The buckle block 52 is provided with a buckle groove 53. The buckle groove 53 can be inserted into the rotation pin 22 and the buckle 23, and the data line is inserted into the inner cavity 11 through the connection hole 21 when the host is connected. The data line exposed outside the wiring hole 21 is collected as a bundle by the buckle 23. After the rotation pin 22 and the buckle 23 pass through the buckle groove 53, the buckle 23 is rotated by ninety degrees to buckle the buckle 52.

The switch door member 904 includes a door slot 51 communicating with the inner cavity 11 at a front end surface of the casing 10, and the bottom wall of the door groove 51 is rotatably mounted with a door 32, the top of the door 32 A sliding groove 31 is defined in the end surface of the door groove 51. An upper sliding groove 26 is defined in the top wall of the door opening groove 51. The sliding door 30 is slidably mounted between the blocking door 32 and the top wall of the door opening groove 51. The upper and lower end faces of the door 30 are provided with a symmetrical slider 28, and the slider 28 is slidably engaged with the upper chute 26 and the sliding groove 31, and the sliding door 30 is pulled out to the right, and the hand is inserted into the inner cavity 11 to open the main body. Switch.

When the host is connected, the data line is inserted into the inner cavity 11 through the wire hole 21, and the data line exposed outside the wire hole 21 is collected as a bundle by the buckle 23, and the rotating pin 22 and the buckle 23 are passed through the buckle groove 53. After that, the buckle 23 is rotated by ninety degrees to buckle the buckle 52.

When in use, the sliding door 30 is pulled out to the right, the hand is extended into the inner cavity 11 to open the switch of the main body, and the frozen ice crystal block 14 is placed to the left end of the water storage block 15, and the water in the water storage block 15 absorbs the ice crystal block. After the temperature of 14 begins to cool down, the cover plate 16 is closed, the driving drive wheel 47 is started to drive the driven wheel 48 to engage, and the water in the water storage block 15 is transported into the pipe network 33 through the water outlet pipe 20, and the air in the bottom outlet 34 is taken. When the temperature is lowered, the starter motor 37 drives the main shaft 39 and the second bevel gear 41 to rotate. The second bevel gear 41 drives the first bevel gear 43, the fan shaft 42 and the sprocket 44 to rotate, and the sprocket 44 drives the chain 45 and the rear side. The fan shaft 42 rotates, the fan shaft 42 drives the blade 46 to rotate, and the air is blown. After the air is filtered by the second filter 25, the air enters the inner cavity 11 upwardly, and the low temperature air is blown up into the inner cavity 11 by the blowing member 901 to enhance the heat dissipation of the main body. The ability to flow water back through the return conduit 19 back into the water storage block 15.

The invention has the advantages that the structure of the invention is simple and convenient to operate, and the cooling component in the main box can reduce the temperature of the water in the water storage block by using the temperature of the ice crystal block, and can be used in the bottom outlet through the pipeline network in the bottom outlet. The air temperature is lowered, and the blowing member provided in the bottom outlet below the main unit can blow the low-temperature air in the bottom outlet into the inner cavity, and the host can inhale the low-temperature air in the inner cavity during heat dissipation, which can better cool down, and is worth promoting.

It will be apparent to those skilled in the art that various modifications of the above embodiment can be made without departing from the spirit and scope of the invention. They all fall within the scope of protection of the present invention. The protection of the invention is subject to the claims appended hereto.

1. A mainframe box, comprising a box body, wherein: the box body is provided with an open inner cavity, the inner cavity is provided with a main body, and the inner cavity rear side wall is provided with an opening rearward a rear outlet, a first filter screen penetrating the rear outlet is inserted into the right end surface of the casing, and the bottom wall of the inner cavity is provided with a bottom outlet opening downward, and the right end surface of the casing is inserted and installed through a second filter screen of the bottom outlet, wherein the bottom outlet is provided with a blowing member for blowing upward, and a cooling member for lowering the temperature of the wind blown by the blowing member is disposed between the bottom outlet and the box, The right side wall of the inner cavity is provided with a connection hole opening to the right, the connection hole can be placed with a data line connected to the main body, and the right end surface of the box body is provided with a fixing component for fixing the data line, the box body The front end is provided with a switch door component that closes the inner cavity and facilitates opening the main body.

2. mainframe box according to claim 1, wherein the blowing component comprises a connecting rod that is vertically symmetric between the left and right walls of the bottom outlet, and between the connecting rods on the left and right sides. a rotating seat, a rotating fan shaft is mounted between the upper and lower rotating seats, the fan shaft is provided with a sprocket, and the chain is driven between the sprocket wheels on the front and rear sides, and the fan shaft is provided with blades, front The fan shaft on the side is provided with a first bevel gear, the left side wall of the bottom outlet is provided with a motor, the right side of the motor is connected to the main shaft, and two shaft stabilizer blocks are arranged between the upper and lower connecting rods. The shaft stabilizing block is rotatably engaged with the main shaft, the right end of the main shaft is provided with a second bevel gear, the second bevel gear meshes with the first bevel gear, and the third inner wall of the bottom outlet is provided with a third a filter screen that activates the motor to drive the fan shaft and the sprocket to rotate, the sprocket drives the chain and the fan shaft on the rear side to rotate, and the fan shaft drives the blade to rotate to start blowing.

3. The mainframe box according to claim 1, wherein the cooling member comprises a foam block located at an inner wall of the bottom outlet and the casing, and the foam block of the vertical portion is provided with a storage block. a water block, an ice crystal block may be disposed in a left end of the water storage block, a left end of the foam block is covered by a screw cover, and a bottom end of the water storage block is connected to a water outlet pipe, and the water outlet pipe extends right into the bottom. a pipe network is connected to the outlet, and the right end of the pipe network is connected to a return pipe. The return pipe is connected to the water storage block after bypassing the bottom outlet, and the pump pipe is provided with a pump chamber. A driving wheel is dynamically mounted between the left and right walls, and a driven wheel is rotatably mounted between the left and right walls of the pump chamber, and the driven wheel is engaged with the driving wheel to place the frozen ice crystal block to the left end of the water storage block. The water in the water storage block absorbs the temperature of the ice crystal block and starts to cool down, covers the cover plate, starts the driving wheel to start the engagement of the driven wheel, and passes the water in the water storage block through the The outlet pipe is conveyed into the pipe network, Air outlet temperature in the bottom lowered, low-temperature air blown by the blowing member upwardly within the interior cavity, the water flows back up through the return line within the water storage block; the main box according to claim 1, wherein the fixing member comprises a rotating pin rotatably mounted on an end surface of the right side of the box, and the right end surface of the rotating pin is provided with a buckle. The right side end surface of the box body is hingedly mounted with a buckle block, and the buckle block is provided with a buckle groove, and the buckle groove can be mated with the rotation pin and the buckle, and the data line is extended through the connection hole when the host is connected Entering into the inner cavity, collecting a data line exposed outside the wire hole through the buckle as a bundle, and after the rotating pin and the buckle pass through the buckle groove, the buckle is Turn ninety degrees to buckle the clasp; the main box according to claim 1, wherein the switch door component comprises a door slot communicating with the inner cavity at a front end surface of the casing, the door bottom of the door The wall rotates to mount the door, the top end surface of the door is provided with a sliding groove, and an upper sliding groove is arranged in the top wall of the door groove, and the sliding door is slidably mounted between the top wall of the door and the door a sliding door having a symmetrical slider on the upper and lower end faces thereof, the slider slidingly engaging the upper sliding groove and the sliding groove, pulling the sliding door to the right, and extending the hand into the inner cavity Turn on the switch of the main unit.
